(19) United States
(12) Patent Application Publication
(10) Pub. No.: US 2013/0020111 A1
(43) Pub. Date: Jan. 24, 2013

(54) SUBSTRATE FOR POWER MODULE PACKAGE AND METHOD FOR MANUFACTURING THE SAME

(71) Applicants: Kyu Hwan Oh, Gyunggi-do (KR); Jong Man Kim, Gyunggi-do (KR); Seog Moon Choi, Seoul (KR); Young Hoon Kwak, Gyunggi-do (KR); Kwang Soo Kim, Gyunggi-do (KR); Young Ki Lee, Gyunggi-do (KR)

(72) Inventors: Kyu Hwan Oh, Gyunggi-do (KR); Jong Man Kim, Gyunggi-do (KR); Seog Moon Choi, Seoul (KR); Young Hoon Kwak, Gyunggi-do (KR); Kwang Soo Kim, Gyunggi-do (KR); Young Ki Lee, Gyunggi-do (KR)

(73) Assignee: SAMSUNG ELECTRO-MECHANICS CO., LTD., Gyunggi-do (KR)

(21) Appl. No.: 13/253,866

(22) Filed: Oct. 5, 2011

(30) Foreign Application Priority Data
Jul. 20, 2011 (KR) 1020110072106

(51) Int. Cl. H05K 1/05; H05K 1/02; H05K 3/10; H05K 1/00

(52) U.S. Cl. 174/255; 174/250; 174/258; 29/846

(57) ABSTRACT

Disclosed herein are a substrate for a power module package and a method for manufacturing the same, including: a base substrate made of a metal material; an anodized layer formed on the base substrate; and a circuit layer formed on the anodized layer, wherein the anodized layer is formed to correspond to circuit patterns on the circuit layer or is formed to be divided into a plurality of areas.

### CROSS REFERENCE TO RELATED APPLICATION

This application claims the benefit of Korean Patent Application No. 10-2011-0072106, filed on Jul. 20, 2011, entitled “Substrate for Power Module Package and Method for Manufacturing the same”, which is hereby incorporated by reference in its entirety into this application.

### BACKGROUND OF THE INVENTION

1. Technical Field

The present invention relates to a substrate for a power module package and a method for manufacturing the same.

2. Description of the Related Art

With the increase in energy consumption around the world, an efficient use of restricted energy has been attracting much attention. Therefore, a use of an inverter adopting an intelligent power module (IPM) for efficiently converting energy in the existing home and industrial appliances has been accelerated.

With the increase in the use of the power module, a demand of a market for high-integration, high-capacity, and small-sized products has increased. As a result, a solution for a problem of heat generation from electronic parts has emerged as an important issue.

Therefore, various methods, such as a method for improving thermal conductivity by changing a material of the substrate, or the like, have been proposed.

Meanwhile, various researches, such as changing a molding material so as to solve a problem in generating cracks due to stress generated at the time of thermal expansion within the power module package, together with the problem of the heat generation, have progressed.

An object of the present invention provides a substrate for a power module package and a method for manufacturing the same selectively performing anodizing treatment on a base substrate of a metal material to prevent cracks from being generated on a substrate for a power module package, thereby improving durability of an overall module and minimizing a thermal resistance value.

### SUMMARY OF THE INVENTION

The present invention has been made in an effort to provide a substrate for a power module package and a method for manufacturing the same selectively performing anodizing treatment on a base substrate of a metal material to prevent cracks from being generated on a substrate for a power module package, thereby improving durability of an overall module and minimizing a thermal resistance value.

According to a preferred embodiment of the present invention, there is provided a substrate for a power module package, including: a base substrate made of a metal material; an anodized layer formed on the base substrate; and a circuit layer formed on the anodized layer, wherein the anodized layer is formed to correspond to circuit patterns on the circuit layer or is formed to be divided into a plurality of areas.

The base substrate may be made of aluminum.

The anodized layer may be made of Al₂O₃.

The base substrate may have a form in which an area other than an area in which the anodized layer is formed is exposed.

According to another preferred embodiment of the present invention, there is provided a method for manufacturing a substrate for a power module package, including: preparing a base substrate made of a metal material; forming an anodized layer on the base substrate; forming a circuit layer on the anodized layer; patterning the circuit layer according to circuit patterns; and patterning the anodized layer, wherein the anodized layer is formed to correspond to the circuit patterns on the circuit layer or is formed to be divided into a plurality of areas.

When the anodized layer is formed to correspond to the circuit patterns, the patterning of the circuit layer according to the circuit patterns may include: forming an etching resist having an open part for the circuit patterns on the circuit layer; and removing and patterning the circuit layer exposed through the open part, and the patterning of the anodized layer may include: removing and patterning the anodized layer exposed through the open part of the etching resist.

When the anodized layer is formed to be divided into the plurality of areas, the patterning of the circuit layer according to the circuit patterns may include: forming an etching resist having an open part for the circuit patterns on the circuit layer; and removing and patterning the circuit layer exposed through the open part, and the patterning of the anodized layer may include: forming and patterning grooves on the anodized layer exposed through the open part of the etching resist, based on the plurality of areas.

The groove may be formed through a scribing process.

The base substrate may be made of aluminum.

The anodized layer may be made of Al₂O₃.

According to another preferred embodiment of the present invention, there is provided a method for manufacturing a substrate for a power module package, including: preparing a base substrate made of a metal material; forming an anodized layer on the base substrate; and forming a circuit layer on the anodized layer, wherein the anodized layer is formed to correspond to the circuit patterns on the circuit layer.

The method may further include prior to the forming of the anodized layer, forming a circuit resist having an open part on the base substrate, wherein at the forming of the anodized layer, the anodized layer is formed by performing anodizing treatment on the open part, and at the forming of the circuit layer, the circuit layer is formed on the anodized layer exposed through the open part.

The anodized layer and the circuit layer may each be formed so as to be partially filled in the open part based on the thickness direction thereof, such that both of the anodized layer and the circuit layer are formed in the open part.

The base substrate may be made of aluminum.

The anodized layer may be made of Al₂O₃.

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a diagram showing a configuration of a substrate for a power module package according to a preferred embodiment of the present invention.

FIG. 2 is a plan view showing a configuration of a substrate for a power module package according to a first preferred embodiment of the present invention.

FIG. 3 is a plan view showing a configuration of a substrate for a power module package according to a second preferred embodiment of the present invention.

FIGS. 4 to 11 are views sequentially showing an example of a method for manufacturing a substrate for a power module package according to a preferred embodiment of the present invention.

FIG. 12 is a diagram for explaining another example of a method for manufacturing a power module package according to a preferred embodiment of the present invention.

FIGS. 13 to 17 are views sequentially showing another example of a method for manufacturing a substrate for a power module package according to a preferred embodiment of the present invention.

FIG. 18 is a diagram for explaining a stress distribution on a substrate for a power module package according to the prior art.

FIG. 19 is a diagram for explaining a stress distribution on a substrate for a power module package according to a preferred embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the subject of the present invention. Terms used in the specification, ‘first’, ‘second’, etc., can be used to describe various components, but the components are not to be construed as being limited to the terms.

Hereinafter, preferred embodiments of the present invention will be described in detail with reference to the accompanying drawings.

Substrate for Power Module Package

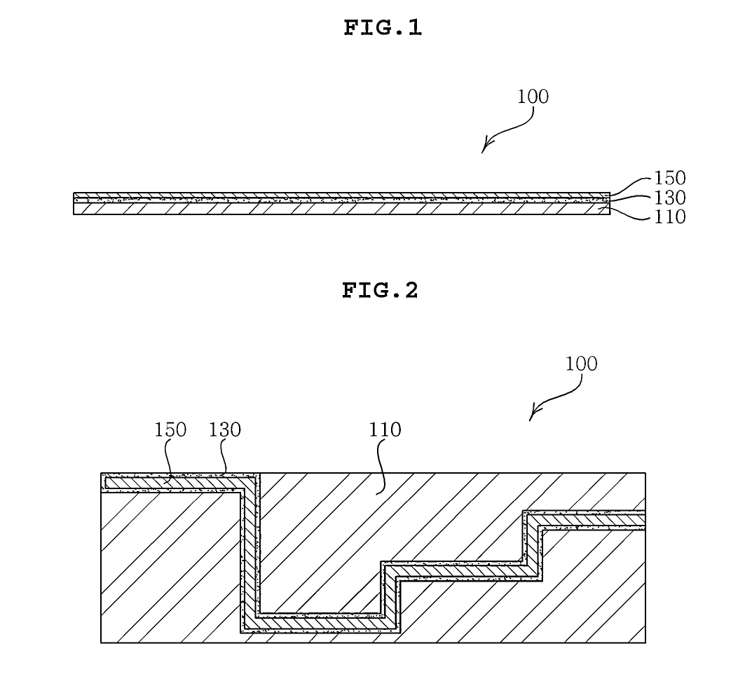

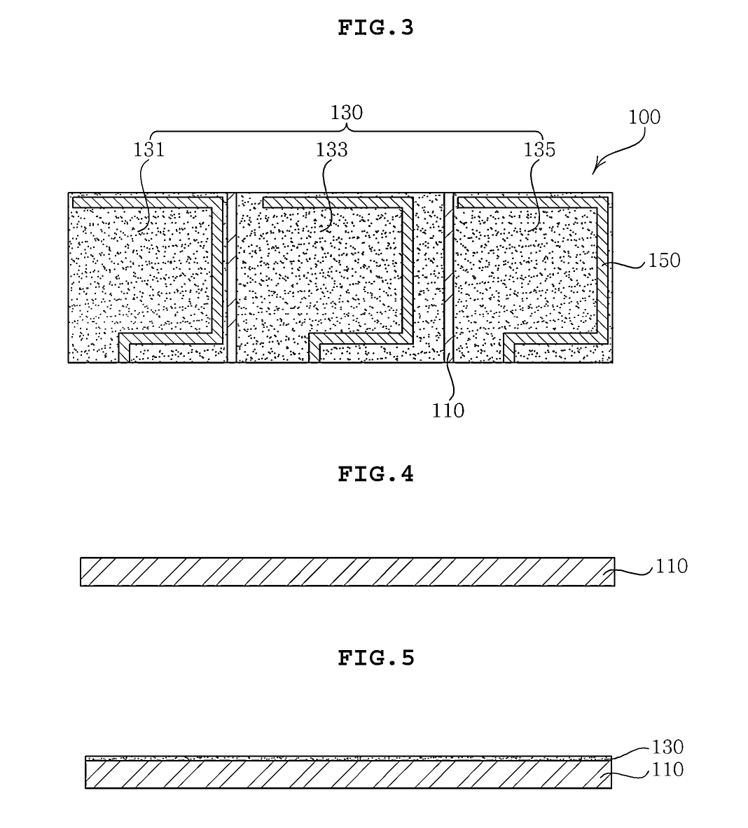

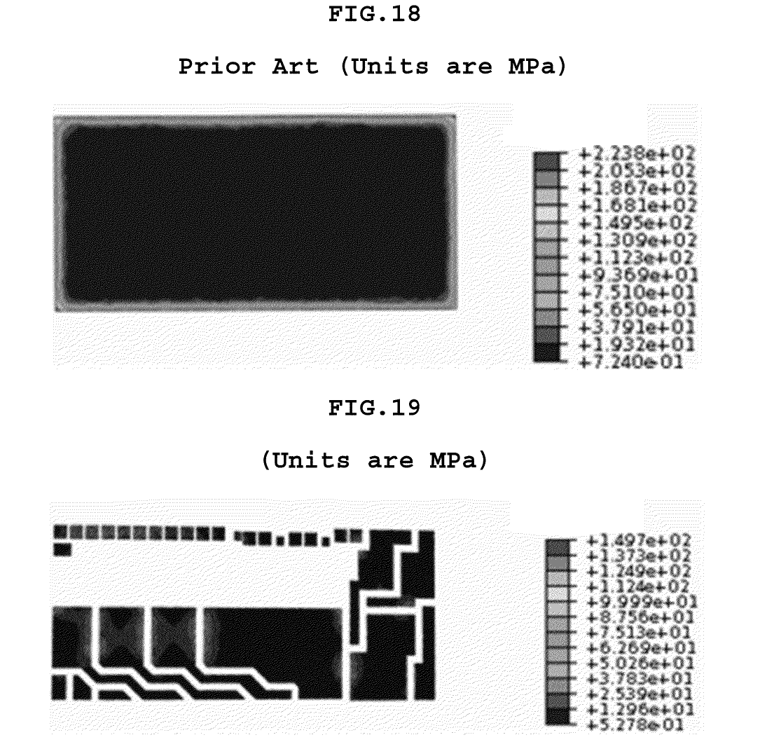

FIG. 1 is a diagram showing a configuration of a substrate for a power module package according to a preferred embodiment of the present invention, FIG. 2 is a plan view showing a configuration of a substrate for a power module package according to a first preferred embodiment of the present invention, and FIG. 3 is a plan view showing a configuration of a substrate for a power module package according to a second preferred embodiment of the present invention. Preferred embodiments of the present invention will be described with reference to FIGS. 18 and 19.

As shown in FIG. 1, a substrate 100 for a power module package includes a base substrate 110 made of a metal material, an anodized layer 130 formed on the base substrate 110, and a circuit layer 150 formed on the anodized layer 130.

In this configuration, the base substrate 110 may be made of aluminum, but is not limited thereto.

In addition, the anodized layer may be made of Al₂O₃, but is not limited thereto.

Meanwhile, as shown in FIGS. 2 and 3, the base substrate 110 may have a form in which an area other than an area in which the anodized layer 130 is formed is exposed.

In addition, as shown in FIG. 2, the anodized layer 130 of the substrate 100 for the power module package may be formed to correspond to circuit patterns on the circuit layer 150.

For convenience of explanation, FIG. 2 shows that a width of the anodized layer 130 is larger than that of the circuit layer 150 based on a plane of the substrate 100 for the power module package; however, the width of the anodized layer 130 may be the same as the width of the circuit layer 150. Further, the preferred embodiment of the present invention is not limited thereto, but the width of the anodized layer 130 may be formed to be larger than that of the circuit layer 150 according to a demand of an operator.

A structure of the anodized layer 130 shown in FIG. 2 may be applied when the circuit patterns on the circuit layer 150 formed on the base substrate 110 are seamlessly connected from one side to the other side based on a plane of a top surface of the base substrate.

In addition, as shown in FIG. 3, the anodized layer 130 of the substrate 100 for the power module package may be formed to be divided into a plurality of areas 131, 133, and 135.

The structure of the anodized layer 130 shown in FIG. 3 may be applied when the circuit patterns on the circuit layer 150 formed on the base substrate 110 are disconnected at least once more from one side to the other side based on a plane of a top surface of the base substrate.

Since the structure of the anodized layer 130 shown in FIGS. 2 and 3 has a structure in which the anodized layer 130 is selectively formed only on the circuit pattern or an arbitrarily necessary area rather than being formed on the entire surface of the substrate 100 for the power module package, stress generated from a portion of the substrate is not spread over the entire surface of the substrate when situations (for example, thermal expansion, external impact, or the like) inducing the stress to the substrate occur.

As a result, it is possible to minimize stress that may occur in the substrate 100 for the power module package and the power module package including the same.

In addition, horizontal cracks may occur between layers (for example, between the base substrate and the anodized layer or between the anodized layer and the circuit layer) configuring the substrate due to the stress generated from the inside of the substrate 100 for the power module package. The anodized layer according to the preferred embodiment of the present invention is selectively formed only in a portion of the base substrate, thereby previously preventing the above-mentioned problems.

FIGS. 18 and 19 each are diagrams showing the stress distributions generated at the time of thermal expansion on the substrate for the power module package according to the preferred embodiment of the prior art and the present invention.

As shown in FIG. 18, it is confirmed that the substrate for the power module package according to the prior art generates a stress of 7.240e−01 to 2.238e+02 MPa at the time of thermal expansion, in particular, a stress of 9.369e+01 to 2.238e+02 MPa is generated along an edge of the substrate.

On the other hand, the substrate for the power module package according to the preferred embodiment of the present invention of FIG. 19 generates the stress of 5.278e−01 to 1.497e+02 MPa at the time of the thermal expansion. From this, it is confirmed that a stress index of the present invention has a remarkably low value than that of the prior art. That is, it may be confirmed that the stress index of the substrate according to the preferred embodiment of the present invention is reduced to about 33% as compared with the substrate of the prior art.

In addition, it is not confirmed that the substrate for the power module package according to the preferred embodiment of the present invention has a high stress index at a specific portion.

The reason is that in the substrate for the power module package according to the preferred embodiment of the present invention, the anodized layer is selectively formed on the base substrate rather than on the entire surface of the base substrate, thereby preventing stress generated at the time of the thermal expansion from being spread over the entire surface of the substrate.

Method for Manufacturing Substrate for Power Module Package-First Preferred Embodiment

FIGS. 4 to 11 are views sequentially showing an example of a method for manufacturing a substrate for a power module package. The case in which the anodized layer is formed to correspond to the circuit patterns will be described by way of example.

First, as shown in FIG. 4, the base substrate 110 made of a metal material is prepared.

In this configuration, the base substrate 110 may be made of aluminum, but is not limited thereto.

Next, as shown in FIG. 5, the anodized layer 130 may be formed on the base substrate 110.

In this case, the anodized layer may be made of Al₂O₃, but is not limited thereto.

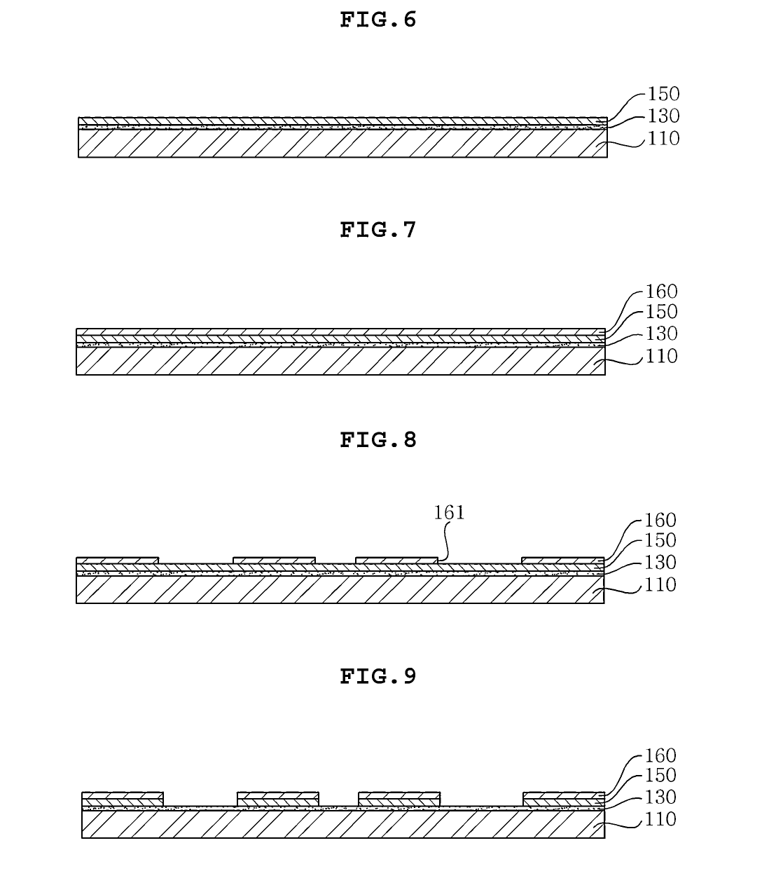

Next, as shown in FIG. 6, the circuit layer 150 may be formed on the anodized layer 130.

Next, as shown in FIGS. 7 to 10, the circuit layer 150 may be patterned according to the circuit patterns.

Describing in more detail, as shown in FIGS. 7 and 8, an etching resist 160 having an open part 161 for a circuit pattern is formed on the circuit layer 150.

In this configuration, as the etching resist 160, a photosensitive resist such as a dry film or a positive liquid photo resist (P-LPR) may be used. The open part 161 may be formed by applying the photosensitive resist to the circuit layer 150, exposing the circuit layer to ultraviolet rays, and then, removing the exposed portion using a developer.

In this case, as shown in FIG. 8, the open part 161 may be formed to expose a portion corresponding to an area to be etched in the circuit layer.

Thereafter, as shown in FIG. 9, the circuit layer 150 is completed by performing the patterning by removing the circuit layer exposed through the open part 161.

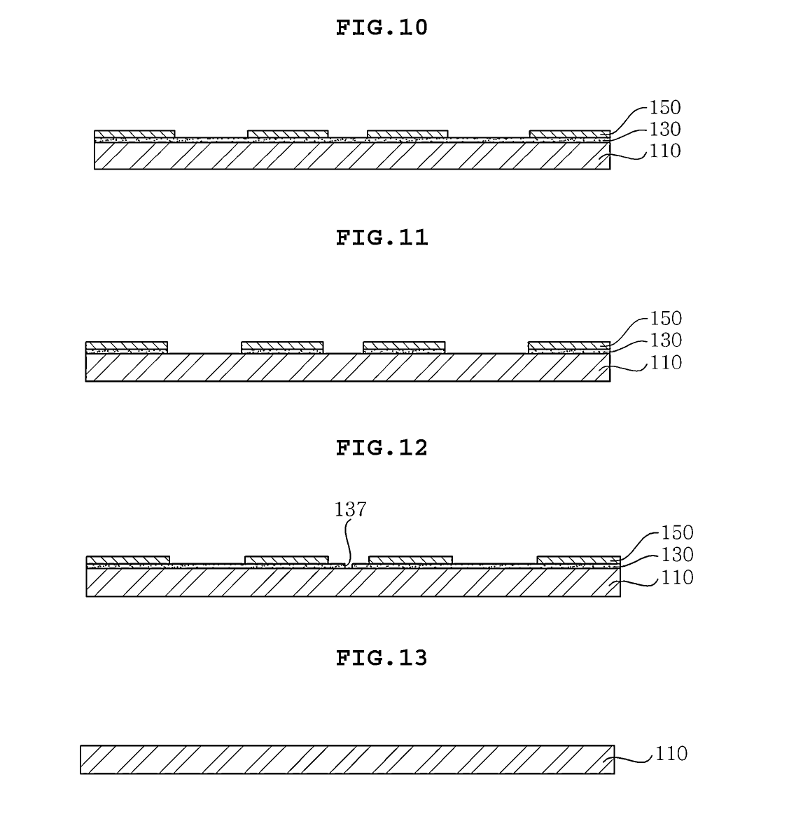

Next, as shown in FIG. 10, the etching resist 160 is removed.

In this case, the etching resist 160 is removed using a stripper such as sodium hydroxide (NaOH), potassium hydroxide (KOH), or the like, but the stripper is not limited thereto.

Next, as shown in FIG. 11, the anodized layer 130 is patterned.

Describing in more detail, the patterning is performed by removing the anodized layer 130 exposed through the open part 161 of the etching resist 160.

Although the etching resist 160 is removed through the process of FIG. 10, the circuit layer 150 formed to correspond to the patterns of the etching resist 160 serves as a resist, such that the anodized layer 130 may be patterned according to the circuit patterns on the circuit layer 150.

Meanwhile, the process of removing the etching resist 160 may be performed after performing the process of patterning the anodized layer 130, according to the demand of the operator.

The base substrate 110 of the substrate 100 for the power module package formed through FIGS. 4 to 11 may have the form in which the area other than the area in which the anodized layer 130 is formed is exposed.

As described above, since the anodized layer 130 has a structure in which the anodized layer 130 is selectively formed only on the circuit pattern or arbitrarily necessary area rather than being formed on the entire surface of the substrate 100 for the power module package, the stress generated from a portion of the substrate is not spread over the entire surface of the substrate when situations (for example, thermal expansion, external impact, or the like) inducing the stress to the substrate occur.

As a result, it is possible to minimize the stress generated from the substrate 100 for the power module package and the power module package including the same.

Method for Manufacturing Substrate for Power Module Package-Second Preferred Embodiment

FIG. 12 is a diagram for explaining another example of a method for manufacturing a substrate for a power module package according to a preferred embodiment of the present invention. Herein, the case in which the anodized layer is formed so as to be divided into a plurality of areas will be described by way of example.

However, the description of the same components as the components of the first preferred embodiment of the present invention among components of the second preferred embodiment of the present invention will be omitted and only different components from the components of the first preferred embodiment of the present invention will be described.

First, the substrate in which the anodized layer 130 is formed on the base substrate 110 and the patterned circuit layer 150 is formed on the anodized layer 130 is prepared, by similarly performing the processes of FIGS. 4 to 10 as described above.

Next, as shown in FIG. 12, the anodized layer 130 exposed through the open part of the etching resist (160 of FIG. 9) is provided with grooves 137 based on a plurality of areas and is patterned.

In this case, as shown in FIG. 3, the plurality of areas mean a plurality of divided areas that are arbitrarily set by an operator and are defined as the area that is set in consideration of the circuit patterns on the circuit layer or arbitrarily set to reduce the stress of the substrate regardless of the circuit pattern.

In addition, as shown in FIG. 3, the grooves 137, which are grooves formed so as to divide the plurality of areas, are connected by a line or a dotted line on a plane of the substrate so as to divide the plurality of areas or are partially formed only on the required portion, but are not limited thereto.

Meanwhile, the groove 137 may be formed by a scribing process, but is not limited thereto and therefore, all processes that can form the groove on the anodized layer 130 may be used.

Method for Manufacturing Substrate for Power Module Package-Third Preferred Embodiment

FIGS. 13 to 17 are views sequentially showing another example of a method for manufacturing a substrate for a power module package according to the preferred embodiment of the present invention. Herein, the case in which the anodized layer is formed to correspond to the circuit patterns on the circuit layer will be described by way of example.

In this case, for convenience of explanation, FIGS. 13 to 17 show the case in which the circuit patterns are different from the circuit patterns of FIGS. 4 to 11 as described above, but it can sufficiently infer that FIGS. 13 to 17 also include the case in which the circuit patterns are the same as the circuit patterns of FIGS. 4 to 11.

First, as shown in FIG. 13, the base substrate 110 made of a metal material is prepared.

In this case, the base substrate 110 may be made of aluminum, but is not limited thereto.

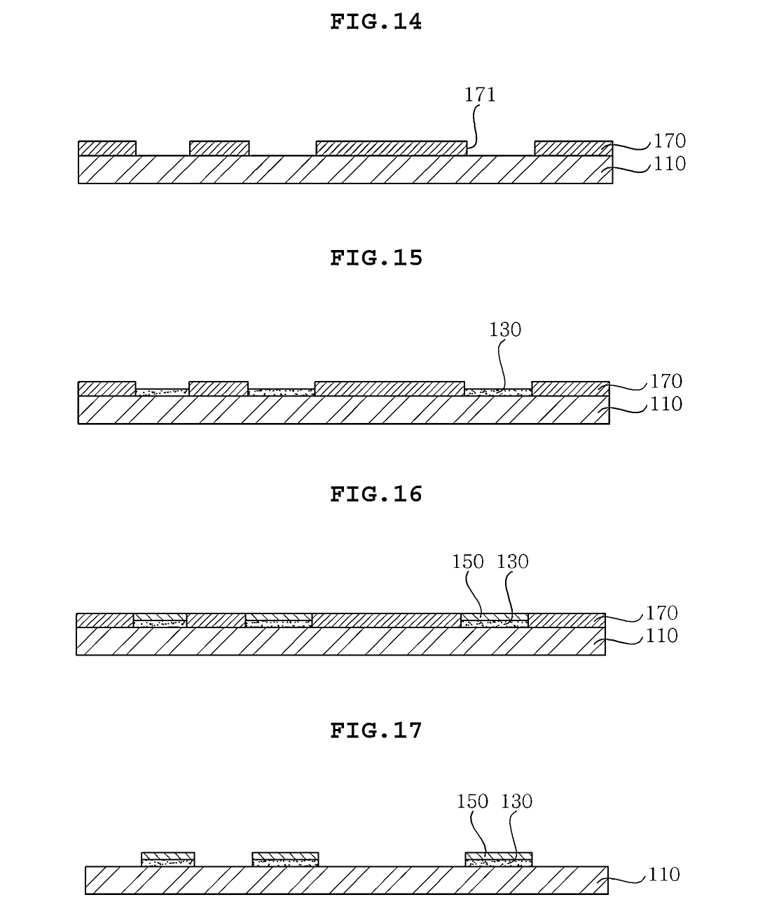

Next, as shown in FIG. 14, a circuit resist 170 having an open part 171 is formed on the base substrate 110.

In this case, as the circuit resist 170, the photosensitive resist such as the dry film or the positive liquid photo resist (P-LPR) may be used. The open part 171 may be formed by applying the photosensitive resist to the base substrate 110, exposing the portions corresponding to the area which the anodized layer and the circuit layer are formed to ultraviolet rays, and then, removing the exposed portion using a developer.

In addition, the pattern width of the circuit resist 170 is determined in consideration of leakage current flowing to the area in which the anodized layer is not formed.

Next, as shown in FIG. 15, the anodized layer 130 is formed on the base substrate 110.

Describing in more detail, the anodized layer 130 is formed by performing the anodizing treatment on the open part 171 of the circuit resist 170.

In this case, the anodized layer 130 is formed so as to fill a portion of the open part 171 based on a thickness direction thereof.

For example, if it is assumed that the thickness of the circuit resist 170 is 100 μm, the thickness of the anodized layer 130 is formed to be 50 μm.

Meanwhile, the anodized layer may be made of Al₂O₃.

Next, as shown in FIG. 16, the circuit layer 150 is formed on the anodized layer 130.

Describing in more detail, the circuit layer 150 is formed on the anodized layer 130 exposed through the open part 171.

In this configuration, the circuit layer 150 is formed in the remaining area of the open part 171 other than a portion of the open part 171 on which the anodized layer is formed.

That is, the anodized layer 130 and the circuit layer 150 are each formed so as to be partially filled in the open part 171 based on the thickness direction thereof, such that both of the anodized layer 130 and the circuit layer 150 are formed in the open part 171.

Next, as shown in FIG. 17, the circuit resist 170 is removed.

In this case, the circuit resist 170 may be removed using a stripper such as sodium hydroxide (NaOH), potassium hydroxide (KOH), or the like, but the stripper is not limited thereto.

As set forth above, the substrate for the power module package and the method for manufacturing the same can selectively form the anodized layer on the base substrate so as to correspond to the circuit patterns on the circuit layer or be divided into the plurality of areas, thereby previously preventing the crack phenomenon by reducing the stress due to the thermal expansion generated on the substrate to improve the durability of the overall module.

In addition, the preferred embodiment of the present invention can previously prevent the cracks from being generated on the substrate for the power module package to prevent the increase of the thermal resistance value caused by the cracks, thereby improving efficiency of the products.

Although the embodiment of the present invention has been disclosed for illustrative purposes, it will be appreciated that a substrate for a power module package and a method for manufacturing the same according to the invention are not limited thereby, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A substrate for a power module package, comprising:
a base substrate made of a metal material;
an anodized layer formed on the base substrate; and
a circuit layer formed on the anodized layer,
wherein the anodized layer is formed to correspond to circuit patterns on the circuit layer or is formed to be divided into a plurality of areas.

2. The substrate for a power module package as set forth in claim 1, wherein the base substrate is made of aluminum.

3. The substrate for a power module package as set forth in claim 1, wherein the anodized layer is made of Al₂O₃.

4. The substrate for a power module package as set forth in claim 1, wherein the base substrate has a form in which an area other than an area in which the anodized layer is formed is exposed.

5. A method for manufacturing a substrate for a power module package, comprising:
preparing a base substrate made of a metal material;
forming an anodized layer on the base substrate;
forming a circuit layer on the anodized layer;
patterning the circuit layer according to circuit patterns; and
patterning the anodized layer,
wherein the anodized layer is formed to correspond to the circuit patterns on the circuit layer or is formed to be divided into a plurality of areas.

6. The method as set forth in claim 5, wherein when the anodized layer is formed to correspond to the circuit patterns,
the patterning of the circuit layer according to the circuit patterns includes:
forming an etching resist having an open part for the circuit patterns on the circuit layer; and
removing and patterning the circuit layer exposed through the open part, and the patterning of the anodized layer includes:
removing and patterning the anodized layer exposed through the open part of the etching resist.

7. The method as set forth in claim 5, wherein when the anodized layer is formed to be divided into the plurality of areas,
the patterning of the circuit layer according to the circuit patterns includes:
forming an etching resist having an open part for the circuit patterns on the circuit layer; and
removing and patterning the circuit layer exposed through the open part, and
the patterning of the anodized layer includes:
forming and patterning grooves on the anodized layer exposed through the open part of the etching resist, based on the plurality of areas.

8. The method as set forth in claim 7, wherein the groove is formed through a scribing process.

9. The method as set forth in claim 5, wherein the base substrate is made of aluminum.

10. The method as set forth in claim 5, wherein the anodized layer is made of Al₂O₃.

11. A method for manufacturing a substrate for a power module package, comprising:
preparing a base substrate made of a metal material;
forming an anodized layer on the base substrate; and
forming a circuit layer on the anodized layer,
wherein the anodized layer is formed to correspond to the circuit patterns on the circuit layer.

12. The method as set forth in claim 11, further comprising prior to the forming of the anodized layer, forming a circuit resist having an open part on the base substrate,
wherein at the forming of the anodized layer,
the anodized layer is formed by performing anodizing treatment on the open part, and
at the forming of the circuit layer,
the circuit layer is formed on the anodized layer exposed through the open part.

13. The method as set forth in claim 12, wherein the anodized layer and the circuit layer are each formed so as to be partially filled in the open part based on the thickness direction thereof, such that both of the anodized layer and the circuit layer are formed in the open part.

14. The method as set forth in claim 11, wherein the base substrate is made of aluminum.

15. The method as set forth in claim 11, wherein the anodized layer is made of Al₂O₃.
